(19) United States
(12) Patent Application Publication
(10) Pub. No.: US 2023/0247851 A1
(43) Pub. Date: Aug. 3, 2023

(54) ELECTRONIC APPARATUS AND PANEL BODY

(71) Applicant: LENOVO (SINGAPORE) PTE. LTD., SINGAPORE (SG)

(72) Inventors: So Nakanishi, YOKOHAMA (JP); Takehito Yamauchi, YOKOHAMA (JP)

(73) Assignee: LENOVO (SINGAPORE) PTE. LTD., SINGAPORE (SG)

(21) Appl. No.: 18/062,482

(22) Filed: Dec. 6, 2022

(30) Foreign Application Priority Data
Jan. 28, 2022 (JP) 202211548

(51) Int. Cl. H10K 50/84

(52) U.S. Cl. CPC H01L 51/5237

(57) ABSTRACT

An electronic apparatus includes: a chassis member having a standing wall; a display panel supported by the chassis member; a bracket having a support surface disposed between an edge portion of the display panel and the standing wall and attached to the display panel; and a bezel member provided in such a manner as to extend over and between the display panel and the standing wall, and fixed to each of the edge portion, the support surface, and the standing wall.

### BACKGROUND OF THE INVENTION

### Field of the Invention

The present invention relates to an electronic apparatus provided with a display panel, and a panel body.

### Description of the Related Art

An electronic apparatus such as a laptop PC is provided with a display panel of liquid crystal or the like (refer to, for example, Japanese Patent No. 6715973).

### SUMMARY OF THE INVENTION

In recent years, as a display panel, an organic EL (OLED: Organic Light Emitting Diode) panel is used instead of a liquid crystal panel in some cases. Organic EL panels are lighter and thinner than liquid crystal panels. Therefore, if an organic EL panel has a mounting structure in which a display surface is covered with a cover glass as in the case of a liquid crystal panel, then the weight of the glass counteracts the advantage of the light weight of the organic EL panel.

To cope with such a problem, the organic EL panel could be attached to a chassis member by using a bezel member, which extends over between the edge portion of the panel and the chassis member, instead of the cover glass. However, the organic EL panel has a narrower non-active area, which is located in the outer periphery of the display surface, than a liquid crystal panel. This makes it difficult to secure an adhesive area of the bezel member in the organic EL panel and therefore difficult to firmly fix the bezel member.

On the other hand, the above-described electronic apparatus is expected to be offered in a lineup that includes a liquid crystal version and an organic EL version of the same model. In this case, it is necessary that the thin organic EL panel can be stably supported by a chassis member for a thick liquid crystal panel.

The present invention has been made in view of the problems with the above-described prior arts, and an object of the invention is to provide an electronic apparatus and a panel body that are capable of stably supporting a display panel with respect to a chassis member.

An electronic apparatus according to the first aspect of the present invention includes: a chassis member having a standing wall; a display panel supported in the chassis member; a bracket having a support surface disposed between an edge portion of the display panel and the standing wall and attached to the display panel; and a bezel member provided in such a manner as to extend over and between the display panel and the standing wall, and fixed to each of the edge portion, the support surface, and the standing wall.

A panel body according to the second aspect of the present invention is a panel body mounted in an electronic apparatus, and includes: a display panel having a display surface; and a bracket which has a support surface extended along an edge portion of the display panel and disposed alongside the display surface, and which is fixed to the display panel.

According to the above-described aspects of the present invention, the display panel can be stably supported with respect to the chassis member.

### BRIEF DESCRIPTION OF THE DRAWINGS

FIG. 1 is a schematic plan view of an electronic apparatus according to an embodiment observed from above.

FIG. 2 is a schematic front view of a first chassis.

FIG. 3 is a schematic front view of a panel body.

FIG. 4 is a schematic sectional view along line IV-IV in FIG. 2.

FIG. 5 is a side sectional view illustrating an operation for mounting a bezel member onto the panel body.

### DETAILED DESCRIPTION OF THE INVENTION

The following will describe in detail an electronic apparatus and a display panel in accordance with the present invention with reference to a preferred embodiment and the accompanying drawings.

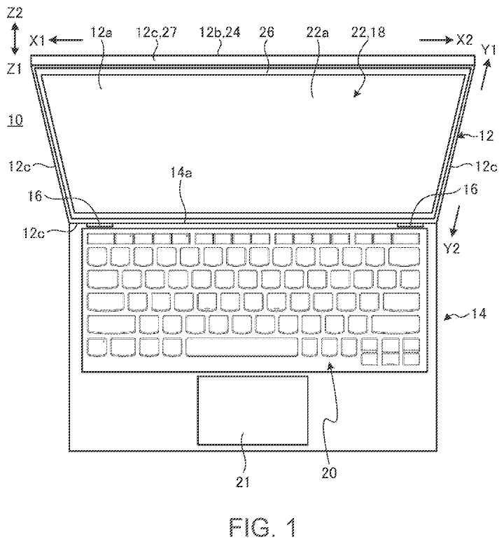

FIG. 1 is a schematic plan view of an electronic apparatus 10 according to an embodiment observed from above. As illustrated in FIG. 1, the electronic apparatus 10 of the present embodiment is a clamshell laptop PC. The electronic apparatus 10 has a configuration in which a first chassis 12 and a second chassis 14 are connected by hinges 16 in a relatively rotatable manner. The first chassis 12 has a panel body 18 mounted therein. The second chassis 14 has a keyboard 20 mounted therein. The electronic apparatus to which the present invention is applicable may be, for example, a stand-alone display device, a tablet PC, a smartphone, or a portable game machine other than a laptop PC.

The second chassis 14 is a flat box body. The second chassis 14 incorporates therein various electronic components such as a motherboard with a CPU and the like mounted thereon, a battery unit, memories, and an antenna device. The keyboard 20 and a touch pad 21 are provided on the upper surface of the second chassis 14.

In the following description, regarding the first chassis 12 and the elements mounted thereon, the direction viewed from a user who views the panel body 18 with the first chassis 12 opened from the second chassis 14 by 90 degrees is defined as a reference, the left-right directions are referred to as X1- and X2-directions, the up-down directions are referred to as Y1- and Y2-directions, and the depth directions are referred to as Z1- and Z2-directions, respectively. The X1- and X2-directions may be collectively referred to as the X-direction, and the Y1- and Y2-directions and the Z1- and Z2-directions may also be referred to in the same manner.

The first chassis 12 is a flat box body that is thinner than the second chassis 14, and provided adjacently to the second chassis 14. The panel body 18 has a display panel 22. The display panel 22 has a display surface 22a facing a front surface 12a, which is a surface of the first chassis 12 on the Z1 side.

The first chassis 12 is composed of a chassis member 24 and a bezel member 26. The chassis member 24 forms a rear surface 12b, which is a surface of the first chassis 12 on the Z2 side. The bezel member 26 forms the peripheral edge portion of the front surface 12a. Side surfaces 12c of the outer periphery of the first chassis 12 are formed of standing walls 27. The standing walls 27 stand from the four peripheral edge portions of the chassis member 24.

The hinges 16 connect the adjacent edges of the first chassis 12 and the second chassis 14. More specifically, the hinges 16 connect the side surface 12c forming the edge portion of the first chassis 12 on the Y2 side, and a side surface 14a, which is the edge portion of the second chassis 14 on the X2 side. The edge portion of the first chassis 12 on the Y2 side may be hereinafter referred to as the adjacent edge portion 12c.

The following will describe more detailed configuration of the first chassis 12.

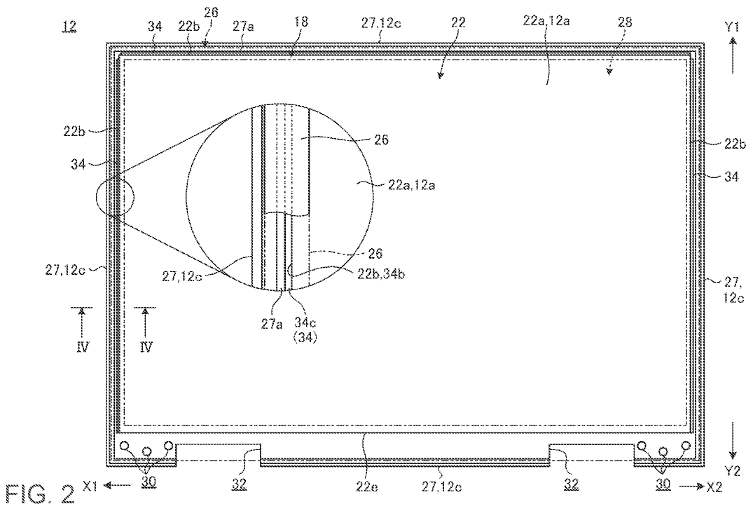

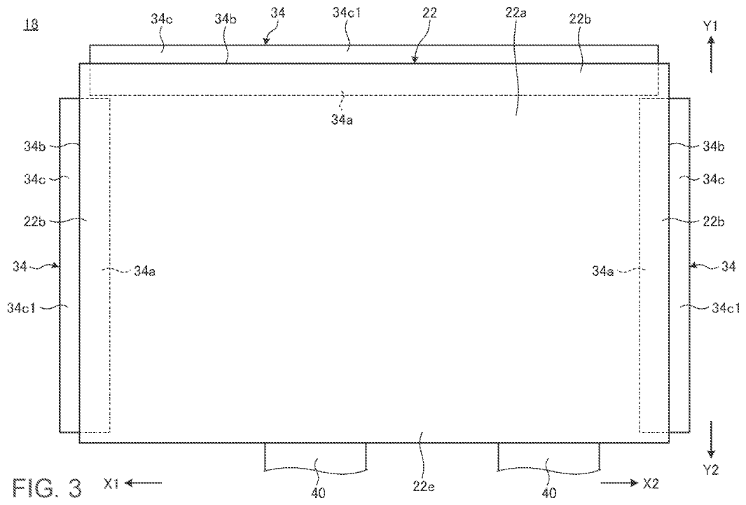

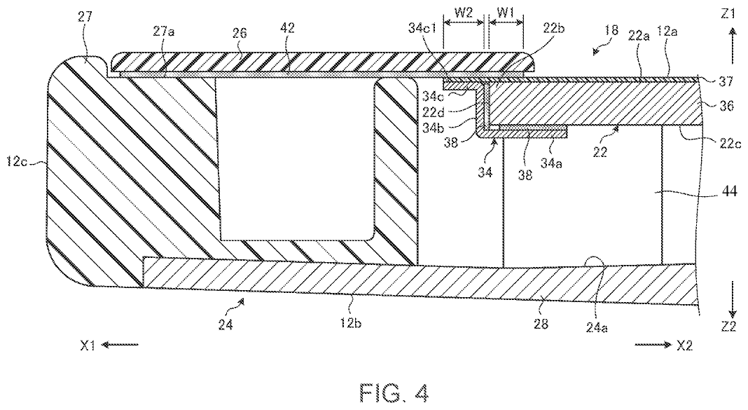

FIG. 2 is a schematic front view of the first chassis 12. FIG. 3 is a schematic front view of the panel body 18. FIG. 4 is a schematic sectional view along line IV-IV in FIG. 2. Referring to FIG. 2, in principle, the bezel member 26 is illustrated by the two-dot chain line, which is an imaginary line, and only a part thereof is illustrated by a solid line in the partial enlarged view surrounded by a circle. In FIG. 3, brackets 34 against the display panel 22 are exaggerated and enlarged so as to clarify the configuration of the brackets 34.

First, the configuration of the chassis member 24 will be described.

As illustrated in FIG. 2, the chassis member 24 has a rectangular cover plate 28 forming the majority including the central portion, and the standing walls 27 that stand along the outer peripheral edge portion of the cover plate 28.

The cover plate 28 of the present embodiment is composed of a carbon fiber reinforced resin plate (CFRP plate) using carbon fiber as the reinforcing fiber. The cover plate 28 may be composed of a resin plate or a metal plate of aluminum, titanium, or the like.

A resin material made by injection molding is joined to the outer peripheral edge portion of the cover plate 28. The standing walls 27 are composed of the resin material. Examples of the resin material that forms the standing walls 27 include polyethylene resin and polypropylene resin, and fiber-reinforced resin containing reinforcing fiber such as glass fiber (e.g., GFRP) in these resins may also be used. The cover plate 28 formed of a carbon fiber reinforced resin plate is light and has high strength, but has problems in machining and shaping workability. Therefore, in the chassis member 24, a resin material is joined around the cover plate 28 and the standing walls 27 and screw holes 30 are formed in this portion.

As illustrated in FIG. 2 and FIG. 4, the standing walls 27 have a fixing surface 27a on the upper surface of a portion facing the central side of the first chassis 12. The fixing surface 27a is a base on which the bezel member 26 is fixed. The standing walls 27 are formed in a frame shape together in such a manner as to surround substantially the entire periphery of the cover plate 28. A portion of a part of the standing wall 27 that forms the adjacent edge portion 12c is divided by a pair of left and right cutout-shaped portions 32. The cutout-shaped portions 32 have a bay-like shape extending from the standing wall 27 to the cover plate 28, and constituent components of the hinges 16 are disposed therein. The screw holes 30 are for fixing the hinges 16. The screw holes 30 are formed in the side portions of the left and right cutout-shaped portions 32.

The configuration of the panel body 18 will now be described.

Referring to FIG. 2 to FIG. 4, the panel body 18 has the display panel 22 and the brackets 34.

Referring to FIG. 4, the display panel 22 of the present embodiment has an organic EL panel 36 and a film 37 laminated on the surface of the organic EL panel 36. The film 37 has, for example, a configuration in which a polarizing film is laminated under a functional film having an anti-glare function, an anti-reflection function and an anti-fingerprint function. The display panel 22 is a touch panel type, but may not be a touch panel type.

The brackets 34 are metal plates made of, for example, SUS. The brackets 34 of this embodiment have a crank shape in a side view. The brackets 34 are fixed to the display panel 22 and extend along edge portions 22b of three sides out of the four sides of the outer periphery of the display panel 22. The three brackets 34 have slightly different overall lengths, but have the same basic configuration, and will be therefore described below without particular distinction.

Referring to FIG. 3 and FIG. 4, each of the brackets 34 has a first plate portion 34a, a second plate portion 34b, and a third plate portion 34c.

The first plate portion 34a is a plate disposed along an XY plane. The first plate portion 34a is fixed to a rear surface 22c of the display panel 22. The second plate portion 34b is a plate bent from the first plate portion 34a in the Z1-direction and disposed along the XZ plane or a YZ plane. The second plate portion 34b is fixed to an outer peripheral edge surface 22d of the display panel 22. The plate portions 34a and 34b are fixed to the surfaces 22c and 22d by using an adhesive material 38 formed of, for example, double-sided adhesive tape.

The third plate portion 34c is a plate bent from the second plate portion 34b in the X1-direction, the X2-direction, or the Y1-direction, and disposed along the XY plane. In other words, the third plate portion 34c is disposed in parallel to and at a different level from the first plate portion 34a. The surface of the third plate portion 34c that faces the Z1 side serves as a support surface 34c1. The support surface 34c1 is disposed between the edge portion 22b of the display panel 22 and the standing wall 27, and disposed alongside on the same XY plane as the display surface 22a of the display panel 22. Thus, the support surface 34c1 becomes the base for supporting the bezel member 26. The tip of the third plate portion 34c may be supported on the chassis member 24.

As illustrated in FIG. 4, in the panel body 18 of the present embodiment, the film 37 disposed on the outermost surface of the display panel 22 extends outward beyond the display surface 22a of the organic EL panel 36 to cover the support surface 34c1. Therefore, the support surface 34c1 supports the bezel member 26 with the film 37 interposed therebetween. The film 37 may not extend to the support surface 34c1. In this case, the support surface 34c1 and the surface of the film 37 are preferably disposed alongside on the same XY plane.

Thus, in the panel body 18 of this embodiment, the display surface 22a of the display panel 22 basically represents the surface of the organic EL panel 36, and the support surface 34c1 is disposed flush with the surface of the organic EL panel 36. However, if, for example, the film 37 does not protrude from the outer peripheral edge surface 22d of the organic EL panel 36, the display surface 22a of the display panel 22 may be regarded as the surface of the film 37. In this case, the support surface 34c1 is preferably disposed flush with the surface of the film 37. In any case, the support surface 34c1 is preferably disposed at a position where the support surface 34c1 can support the bezel member 26 on the same plane as the display panel 22.

As illustrated in FIG. 2 and FIG. 3, the bracket 34 is not attached to an edge portion 22e disposed along the adjacent edge portion 12c out of the four outer peripheral sides of the display panel 22. As illustrated in FIG. 3, in the display panel 22, wirings 40 such as flexible printed circuit boards (FPCs) are routed to the second chassis 14 through the edge portion 22e. For this reason, the bracket 34 is not provided on the edge portion 22e mainly for the purpose of avoiding the interference with the wirings 40.

The mounting structure of the bezel member 26 will now be described.

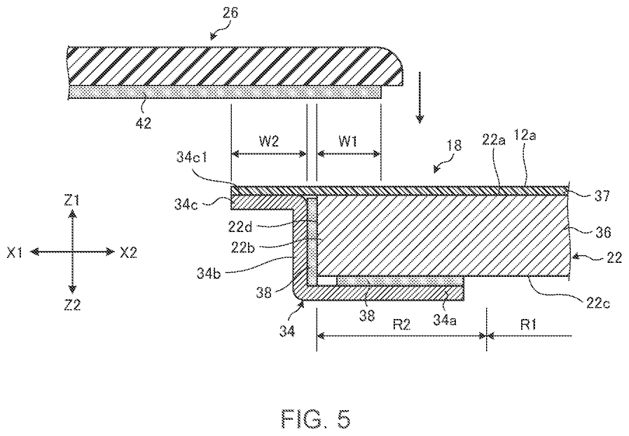

FIG. 5 is a side sectional view illustrating the operation for mounting the bezel member 26 onto the panel body 18.

The bezel member 26 is a member made by, for example, forming a thin plate of a resin or the like into a frame shape. As illustrated in FIG. 2 and FIG. 4, the bezel member 26 is provided in such a manner as to extend over and between the edge portions 22b and 22e of the display panel 22 and the standing walls 27 to surround the display panel 22.

As illustrated in FIG. 4 and FIG. 5, the bezel member 26 is disposed, extending over the support surface 34c1 of the bracket 34. The bezel member 26 is bonded, using an adhesive material 42, to the surfaces of the edge portions 22b and 22e, the support surface 34c1, and the fixing surface 27a. The adhesive material 42 is, for example, double-sided adhesive tape. Thus, the bezel member 26 supports the edge portions 22b and 22e of the display panel 22 onto the chassis member 24 and also covers the gap between the edge portions 22b, 22e and the standing walls 27.

Meanwhile, as illustrated in FIG. 5, the organic EL panel 36 is characterized by having a wider active region R1, which is a display area of the display surface 22a, and a narrower outer peripheral non-active region R2, which is a non-display region, as compared with a conventional liquid crystal panel. Further, the bezel member 26 must be attached to the non-active region R2 in such a manner as not to cover the active region R1. The width of the non-active region R2 is, for example, 1.6 mm for the organic EL panel and 2.5 mm for the liquid crystal panel.

Therefore, the display panel 22 of the present embodiment using the organic EL panel 36 has a problem that it is difficult to secure a bonding area for the bezel member 26. Specifically, as illustrated in FIG. 4 and FIG. 5, the bonding surface of the bezel member 26 can only secure a narrow area over a width W1. The width W1 is, for example, 0.27 mm. On the other hand, in the conventional liquid crystal panel, the width W1 of the bonding surface of the bezel member 26 that could be secured was, for example, approximately 1.75 mm.

As described above, the bezel member 26 of the present embodiment has a small area of bonding to the display panel 22, thus posing a problem that the bezel member 26 easily peels off from the display panel 22.

Here, the electronic apparatus 10 of the present embodiment is expected also to reduce cost by using the same chassis member 24 for a model having the organic EL panel 36 and a model having a liquid crystal panel. For this reason, as illustrated in FIG. 4, the chassis member 24 has a thickness in the Z-direction that can accommodate a liquid crystal panel that is thicker than the organic EL panel 36. Hence, the display panel 22 using the organic EL panel 36 has to have a mounting structure that is significantly lifted from an inner surface 24a of the chassis member 24. As a result, the electronic apparatus 10 poses another problem that the edge portions 22b of the display panel 22 tend to sink in the Z2-direction, causing the bezel member 26 to be even more likely to peel off. Reference numeral 44 in FIG. 4 denotes a sponge interposed between the display panel 22 and the inner surface 24a. The sponge 44 may be omitted.

Therefore, as described above, the brackets 34 are fixed to the edge portions 22b of the display panel 22 in the panel body 18 of the present embodiment. Each of the brackets 34 has the support surface 34c1 adjacent to the side portion of the display surface 22a to expand the bonding area of the adhesive material 42 of the bezel member 26. Specifically, a width W2 of the support surface 34c1 illustrated in FIG. 4 and FIG. 5 is equal to or greater than the width W1, and approximately 1 mm, for example, can be secured. Consequently, in the electronic apparatus 10, the total width from the end of the width W1 to the end of the width W2 makes it possible to expand the bonding area of the bezel member 26 to approximately the same extent as in the case of the conventional liquid crystal panel.

As a result, the panel body 18 can secure a sufficient bonding area for the bezel member 26 while using the organic EL panel 36, for which it is difficult to secure a bonding area for the adhesive material 42, so that it is possible to suppress the peeling or lifting of the bezel member 26 from the display panel 22 of the bezel member 26. In addition, since the bezel member 26 is firmly fixed to the panel body 18, the bezel member 26 functions as a bridge, thus suppressing the sinking of the display panel 22 itself. At this time, the brackets 34 are fixed to the display panel 22, so that there is an advantage that the flatness with respect to the display surface 22a is easily secured. As described above, in the electronic apparatus 10 of the present embodiment, the display panel 22 can be stably supported with respect to the chassis member 24.

Further, in the panel body 18, the brackets 34 fixed to the edge portions 22b reinforce the organic EL panel 36, thus making it possible to suppress bending deformation due to the thinness of a module, which is a problem with an organic EL panel.

In the panel body 18, the brackets 34 are composed of crank-shaped metal plates, which enables the brackets 34 to obtain high strength despite being formed of the thin metal plates. Further, the brackets 34 can be stably fixed to the edge portions 22b of the display panel 22 with almost no gap due to the crank shape. At this time, the brackets 34 are fixed not only to the rear surface 22c of the display panel 22 but also to the outer peripheral edge surface 22d, so that the brackets 34 can be fixed to the display panel 22 more firmly and the support strength of the bezel member 26 is also improved.

The brackets 34 may be provided also on the edge portion 22e. As described above, however, the edge portion 22e has the wirings 40, thus making it difficult to install the brackets 34. Further, the edge portion 22e corresponds to the bottom side of the display surface 22a of the display panel 22. Therefore, even if the bracket 34 is not provided on the edge portion 22e, the non-active region R2 is easily ensured to be thicker than the other edge portions 22b, and the fixing strength problem of the bezel member 26 is smaller than that of the other edge portions 22b. The installation positions of the brackets 34 can be changed as appropriate, and the brackets 34 may be installed, for example, only on the two left and right sides along the Y-direction. Further, the brackets 34 do not necessarily have to be configured to extend over substantially the entire length of the edge portions 22b. For example, the brackets 34 may be configured by short piece components, and a plurality of the pieces may be appropriately arranged on the edge portions 22b.

It is needless to say that the present invention is not limited to the above-described embodiment, and can be freely modified within a range not departing from the gist of the present invention.

The display panel 22 may be other than the organic EL panel 36 and may be, for example, a liquid crystal panel.

The above description has illustrated the structure of the chassis member 24 having the thickness compatible with a display panel using a liquid crystal panel. However, the chassis member 24 may have, for example, a dedicated thin structure for the display panel 22 using the organic EL panel 36. In this case also, the brackets 34 can be effectively used, because the peeling problem of the bezel member 26 still remains even though the sinking of the display panel 22 can be suppressed.

In the above, the support surfaces of the brackets have been described as being on the same plane as the display surface of the display panel. Here, being on the same plane does not prevent the presence of a slight step or positional deviation.

1. An electronic apparatus comprising:
a chassis member having a standing wall;
a display panel supported in the chassis member;
a bracket having a support surface between an edge portion of the display panel and the standing wall, and attached to the display panel; and
a bezel member extends over and between the display panel and the standing wall, and is fixed to the edge portion,
the support surface, and the standing wall.

2. The electronic apparatus according to claim 1,
wherein the support surface is alongside and on a same plane as a display surface of the display panel.

3. The electronic apparatus according to claim 1,
wherein the bracket extends along the edge portion of the display panel.

4. The electronic apparatus according to claim 3,
wherein the bracket is formed of a metal plate having a crank shape.

5. The electronic apparatus according to claim 4,
wherein the bracket has:
a first plate portion fixed to a rear surface of the display panel;
a second plate portion bent from the first plate portion and disposed along an outer peripheral edge surface of the display panel; and
a third plate portion bent from the second plate portion and having the support surface.

6. The electronic apparatus according to claim 5,
wherein the second plate portion is fixed to the outer peripheral edge surface.

7. The electronic apparatus according to claim 3, further including:
a first chassis having a rectangular outline, a rear surface thereof being formed by the chassis member;
a second chassis having a rectangular outline and adjacent to the first chassis; and
a hinge that connects adjacent edge portions of the first chassis and the second chassis in a relatively rotatable manner,
wherein the display panel has a rectangular outline along the outline of the first chassis, and
the bracket is on three sides of three edge portions of the display panel.

8. The electronic apparatus according to claim 1,
wherein the display panel is an organic EL panel.

9. A panel body mounted in an electronic apparatus, comprising:
a display panel having a display surface; and
a bracket having a support surface that extends along an edge portion of the display panel and is disposed alongside the display surface, and fixed to the display panel.

10. The panel body according to claim 9,
wherein the bracket has:
a first plate portion fixed to a rear surface of the display panel;
a second plate portion bent from the first plate portion, disposed along an outer peripheral edge surface of the display panel, and fixed to the outer peripheral edge surface; and
a third plate portion being bent from the second plate portion and having the support surface.

11. The panel body according to claim 9,
wherein the display panel has a rectangular outline, and
the bracket is on three sides of the edge portion of the display panel.
